(19) United States
(12) Patent Application Publication
(10) Pub. No.: US 2016/0044817 A1
(43) Pub. Date: Feb. 11, 2016

(54) FIXATION STRUCTURE FOR STORAGE MODULE

(71) Applicant: TPV-INVENTA Technology Co., Ltd., Taipei (TW)

(72) Inventors: Shih-Yu HSIEH, Taipei City (TW); Cheng-Cheng LEE, Taipei City (TW); Feng-Yu CHANG, Taipei City (TW); Shih-Ti SUN, Taipei City (TW)

(21) Appl. No.: 14/692,392

(22) Filed: Apr. 21, 2015

(30) Foreign Application Priority Data
Aug. 8, 2014 (TW) 103214229

(51) Int. Cl. H05K 7/14; H05K 7/18; H05K 5/04; H05K 5/02; H05K 5/03

(52) U.S. Cl. CPC H05K 7/14; H05K 5/0239; H05K 5/03; H05K 5/04; H05K 7/18

(57) ABSTRACT

The disclosure provides a fixation structure, for accommodating and fixing a storage module, including an accommodating housing. The accommodating housing includes a fixed housing and a movable housing. The fixed housing includes a bottom frame and a side frame. The side frame stands on three adjacent sides of the bottom frame to form an opening therebetween. The movable housing is detachably installed on the bottom frame to close the opening and forms an accommodation room with the fixed housing. The storage module is located in the accommodation room. The fixed housing and the movable housing are made of metal.

### CROSS-REFERENCE TO RELATED APPLICATIONS

This non-provisional application claims priority under 35 U.S.C. §119(a) on Patent Application No(s). 103214229 filed in Taiwan, R.O.C. on Aug. 8, 2014, the entire contents of which are hereby incorporated by reference.

### BACKGROUND OF THE INVENTION

1. Technical Field

The disclosure relates to a fixation structure, more particular to a fixation structure for a storage module.

2. Background

With the improvement of technology, the processing of electronic devices becomes faster, and the functions of electronic devices are varied. People depend on various kinds of electronic devices to satisfy their different demands in daily life.

However, to satisfy the users' demand, electronic devices need more storage modules for the drastically increased information storage requirements. For example, the electronic device is a server having multiple hard disks. The hard disks are individually installed on hard disk drive trays, and the hard disk drive trays with the hard disks can be assembled to or replaced from the server individually.

In the prior art, the hard disks need to take grounding and anti-electrostatic process. Normally, the hard disk drive trays are made by plastic, so the conducting structures like gasket or conductive cushion are set on the hard disk driver tray to ground, to avoid electromagnetic disturbance (i.e., electromagnetic interference, EMI) and electrostatic generation. However, setting gasket or conductive cushion increases the overall cost of production.

In addition, the common hard disks are screwed on the hard disk driver tray by multiple screws, but the screwing process increases the assembling time, disassembling time and overall cost of production.

### SUMMARY

One embodiment of the present disclosure discloses a fixation structure for storage module to accommodate and fix the storage module. The fixation structure for storage module comprises an accommodate housing. The accommodate housing comprises a fixed housing and a movable housing, wherein the fixed housing and the movable housing are made of metal. The fixed housing includes a bottom frame and a side frame, wherein the side frame stands on three adjacent sides of the bottom frame to form an opening therebetween. The movable housing is detachably installed on the bottom frame for closing the opening so as to form an accommodating room with the fixed housing, and the storage module is installed inside the accommodating room.

### BRIEF DESCRIPTION OF THE DRAWINGS

The present disclosure will become more fully understood from the detailed description given herein below, along with the accompanying drawings which are for illustration only, thus are not limitative of the present disclosure, and wherein:

FIG. 1 is a perspective view of a storage module and a fixation structure according to an embodiment of the present disclosure;

FIG. 2 is an exploded view of the storage module and the fixation structure according to the embodiment of the present disclosure;

FIG. 3 is an exploded view of the fixation structure according to the embodiment of the present disclosure;

FIG. 4 is a schematic view of the storage module installed on the fixation structure during a first assembling step according to the embodiment of the present disclosure;

FIG. 5 is a schematic view of the storage module installed on the fixation structure during the second assembling step according to the embodiment of the present disclosure;

FIG. 6 is an exploded view of installing the storage module with a fixed housing on a base board according to the embodiment of the present disclosure; and

FIG. 7 is a cross-sectional side view of the storage module assembled on the fixation structure according to the embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

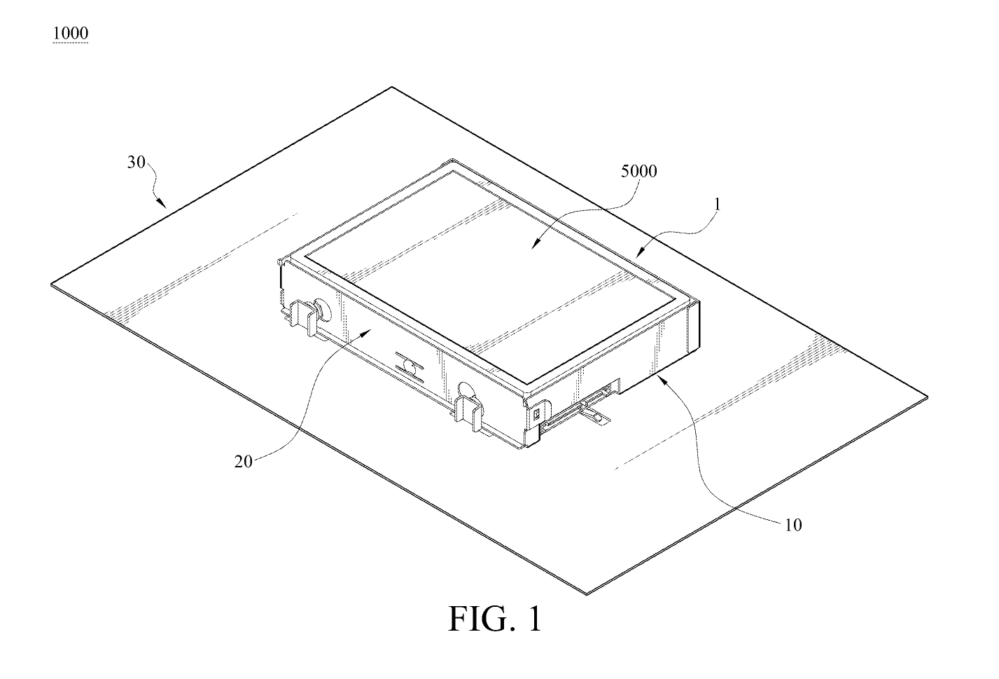

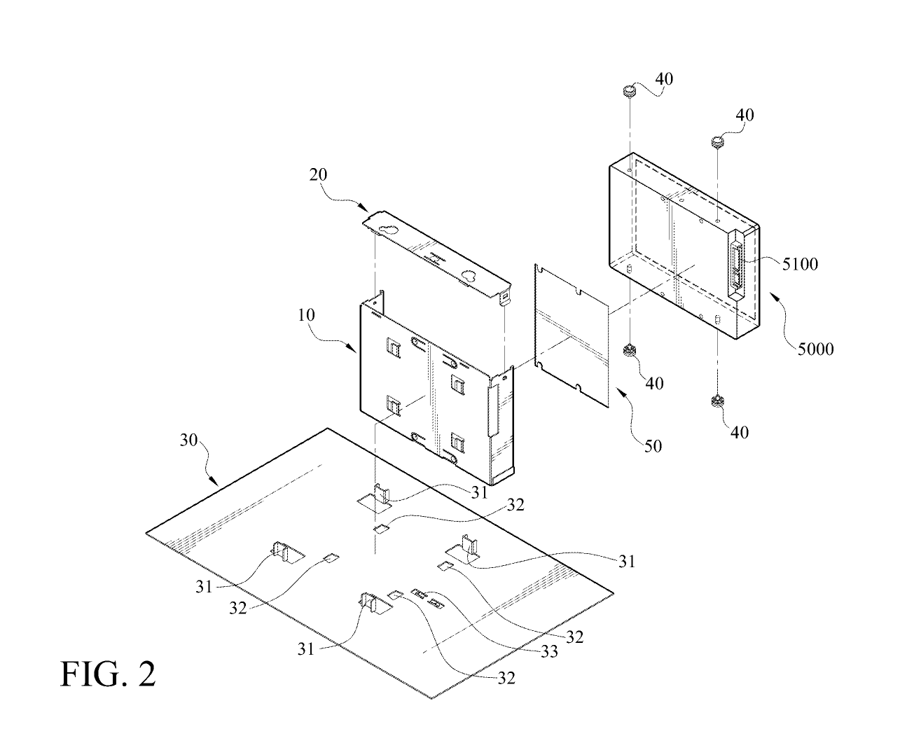

The following descriptions of the present disclosure, electronic device, are referring to FIG. 1 and FIG. 2, wherein FIG. 1 is a perspective view of a storage module and a fixation structure according to an embodiment of the present disclosure, and FIG. 2 is an exploded view of the storage module and the fixation structure according to the embodiment of the present disclosure.

Referring now to FIG. 1, one embodiment of the present disclosure discloses a fixation structure 1000 for accommodating and fixing a storage module 5000. In this embodiment, storage module 5000 is a hard disk drive, but the present disclosure is not limited thereto.

The fixation structure 1000 of the storage module 5000 comprises an accommodating housing 1. In this and some other embodiments, the fixation structure 1000 further comprises a base board 30 on which the accommodating housing 1 is detachably installed. In this and some other embodiments, the fixation structure 1000 further comprises four buffer pins 40 installed between the storage module 5000 and the fixation structure 1000 for buffering shocks of the storage module 5000 during operation.

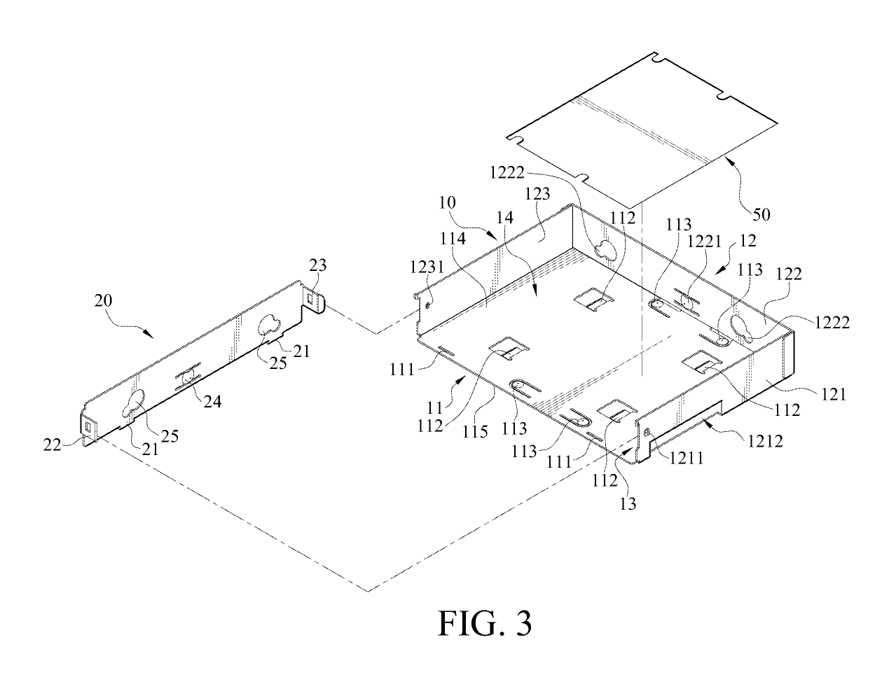

Referring now to FIG. 2 and FIG. 3, the followings introduce the detailed structure of accommodating housing 1. FIG. 3 is an exploded view of the fixation structure according to the embodiment of the present disclosure. The accommodating housing 1 comprises a fixed housing 10 and a movable housing 20. The movable housing 20 is detachably installed on the fixed housing 10, and the movable housing 20 forms an accommodating room 14 with the fixed housing 10 so as to accommodate the storage module 5000.

It is worth to note that the fixed housing 10 and the movable housing 20 are made by metal. As a result, the fixed housing 10 and the movable housing 20 are directly electrically connected to a conducted surface of the storage module 5000, which is a metal surface, for grounding. Furthermore, the storage module 5000 is surrounded by the fixed housing 10 and the movable housing 20 for avoiding electrostatic interference.

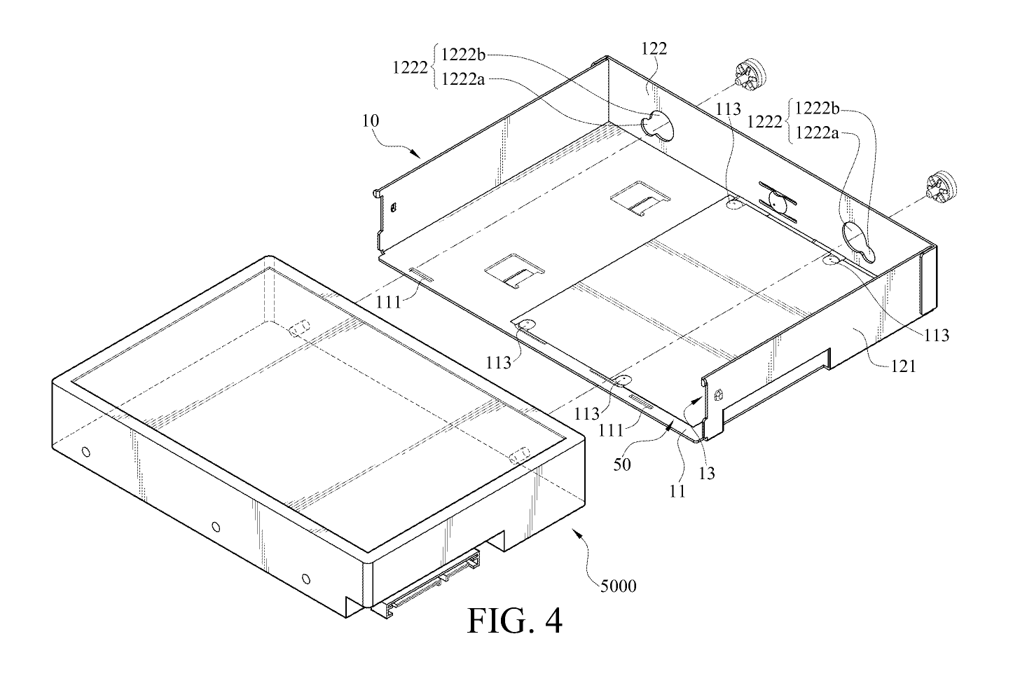

Referring now to FIG. 2 to FIG. 4, FIG. 4 is a schematic view of the storage module installed on the fixation structure during a first assembling step according to the embodiment of the present disclosure. Fixed housing 10 comprises a bottom frame 11 and a side frame 12. The side frame 12 stands on three adjacent sides of the bottom frame 11, respectively, to form an opening 13 therebetween. Furthermore, the side frame 12 comprises a first side frame 121, a second side frame 122 and a third side frame 123, which are fixed on the three adjacent side of the bottom frame 11, respectively. Two opposite ends of the second side frame 122 are connected to one end of the first side frame 121 and one end of the third side frame 123, respectively, and the opening 13 is formed between the other end of the first side frame 121 and the other end of the third side frame 123. The storage module 5000 can enter the accommodating room 14 formed by the movable housing 20 and the fixed housing 10 through the opening 13. The storage module 5000 comprises a circuit board (not shown) facing the bottom frame 11.

In this and some other embodiments, the bottom frame 11 comprises a plurality of fixing slots 111, a plurality of hooks 112, a plurality of elastic electrically connecting plates 113, a first surface 114 and a second surface 115. The first surface 114 is opposite to the second surface 115. The fixing slots 111, which extend through the first surface 114 and the second surface 115, are located on one side of the bottom frame 11. The hooks 112 extend outward from the second surface 115. The elastic electrically connecting plates 113, which extend toward the accommodation room 14, are directly connected to the storage module 5000 to enhance the grounding effect.

In this and some other embodiments, the first side frame 121 of the side frame 12 has a fixing bulge 1211 and a through hole 1212. The fixing bulge 1211 is located on an end of the first side frame 121 away from the second side frame 122. When the storage module 5000 is set in the fixed housing 10, the through hole 1212 exposes a connecting slot 5100 of the storage module 5000.

In this and some other embodiments, the second side frame 122 of the side frame 12 comprises an electrically connecting part 1221 and a plurality of keyhole-shaped installing holes 1222. The electrically connecting part 1221 extends toward the accommodating room 14 to be electrically connected to the storage module 5000 for grounding. Furthermore, each keyhole-shaped installing hole 1222 has a releasing part 1222a and a fixing part 1222b. The width of the fixing part 1222b is narrower than the releasing part 1222a. The buffer pin 40 is able to stick in or get out of the keyhole-shaped installing hole 1222 from the releasing part 1222a and move toward the fixing part 1222b for fixation.

In this and some other embodiments, the third side frame 123 of the side frame 12 comprises a fixing bulge 1231. The fixing bulge 1231 is located on an end of the third side frame 213 away from the second side frame 122.

Referring now to FIG. 3, the following describes the detailed structure of the movable housing 20. In this and some other embodiments, the movable housing 20 comprises a plurality of blocks 21, a plurality of fixing notches 22 and 23, an electrically connecting part 24 and a plurality of keyhole-shaped installing holes 25. The block 21 of the movable housing 20 is detachably installed in the fixing slot 111 of the bottom frame 11. The fixing notches 22 and 23 are located at the two opposite ends of the movable housing 20 and face the second side frame 122, respectively. The fixing bulges 1211 and 1231 and the fixing notches 22 and 23 are interlocked with each other, respectively, to close the opening 13. The electrically connecting part 24 extends toward the accommodation room 14 and is electrically connected to the storage module 5000 for grounding.

In this and some other embodiments, the accommodating housing 1 further comprises an electrically isolating board 50 installed on the bottom frame 11 with the elastic electrically connecting plates 113 exposed. The electrically isolating board 50 separates the bottom frame 11 and the circuit board (not shown) of the storage module 5000 for avoiding a short circuit between the storage module 5000 and the bottom frame 11.

Referring now to FIG. 2, the following describes the detailed structure of the base board 30. In this and some other embodiments, the base board 30, where a plurality of locating walls 31 are set, comprises a plurality of interlock grooves 32 and a plurality of elastic electrically connecting plates 33. The hooks 112 of the bottom frame 11 are detachably interlocked to the interlock grooves 32 of the base board 30, respectively. When the buffer pins 40 are installed in the keyhole-shaped installing holes 1222 and 25, one ends of the buffer pins 40 are pressed against the storage module 5000, respectively, and the other ends of the buffer pins 40 are pressed against the locating walls 31, respectively, for fixing the storage module 5000 on the base board 30. Furthermore, the elastic electrically connecting plates 33 extend toward the bottom frame 11 for directly electrically connecting to the bottom frame 11. Therefore, the storage module 5000 is directly electrically connected to the bottom frame 11 for enhancing the grounding effect.

It is worthy to note that the base board 30 is made by metal and directly electrically connected to the bottom frame 11 for grounding.

Referring now to FIG. 4, the following describes assembly steps of the storage module 5000. First, two of the buffer pins 40 are respectively installed in the two releasing parts 1222a of the keyhole-shaped installing holes 1222 on the second side frame 12 of the fixed housing 10, and then the two buffer pins 40 are respectively moved to the two fixing parts 1222b of the keyhole-shaped installing holes 1222. Then, the storage module 5000 is slid into the fixed housing 10 through the opening 13, and one end of the buffer pins 40 are pressed against the side of the storage module 5000 nearing the second side frame 122.

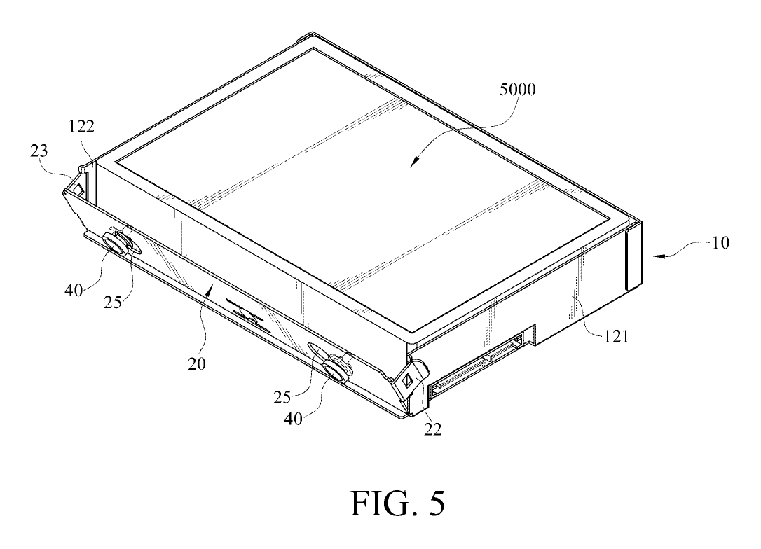

Referring now to FIG. 5, it is a schematic view of the storage module installed on the fixation structure during the second assembling step according to the embodiment of the present disclosure. Next, the other two buffer pins 40 are respectively installed in the two installing holes 25 of the movable housing 20. Lastly, the blocks 21 are pivotally installed in the fixing slot 111 of the bottom frame 11 and make the fixing notches 22 and 23 interlock with the fixing bulges 1211 and 1231 on the first side frame 121 and the third side frame 123, respectively. In this way, the storage module 5000 is fixed inside the accommodating housing 1 formed by the fixed housing 10 and the movable housing 20.

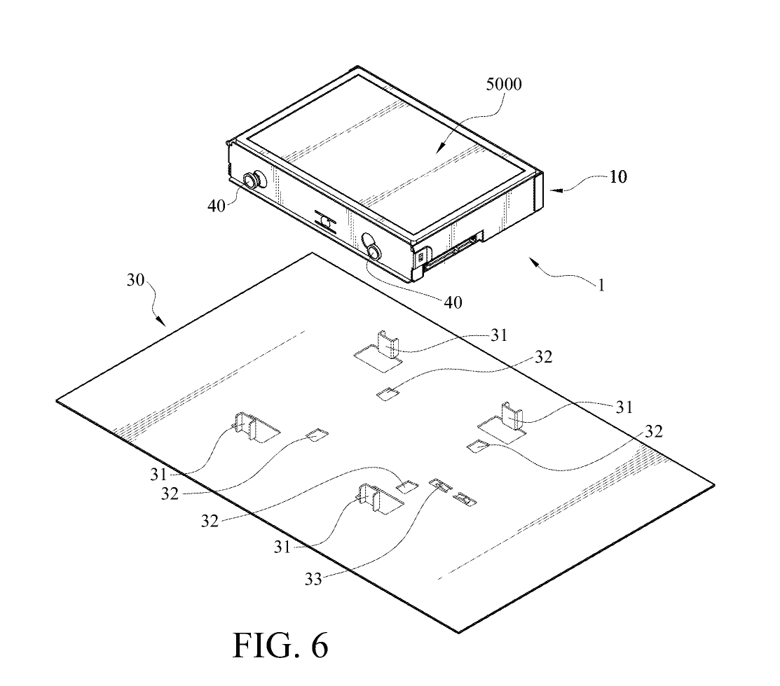

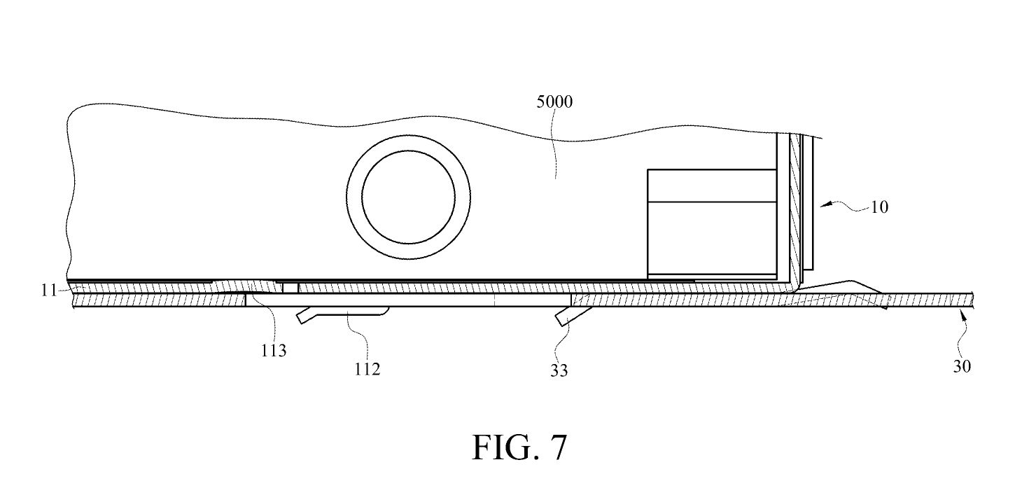

Please refer now to FIG. 6 and FIG. 7. FIG. 6 FIG. 6 is an exploded view of installing the storage module with a fixed housing on a base board according to the embodiment of the present disclosure. FIG. 7 is a cross-sectional side view of the storage module assembled on the fixation structure according to the embodiment of the present disclosure. The accommodating housing 1, where the storage module 5000 is loaded, is installed and fixed on the base board 30 by interlocking the hooks 112 with the interlock grooves 32, respectively. Moreover, the other end of the buffer pins 40 are respectively pressed against the locating walls 31 so as to fix the storage module 5000 firmly on the base board 30. Therefore, the assembling of the storage module 5000 is finished.

As shown in FIG. 7, the storage module 5000 is directly pressed against and connected to the elastic electrically connecting plates 113 of the bottom frame 11, and the bottom frame 11 is directly pressed against and connected to the elastic electrically connecting plates 33 of the base board 30. Therefore, the storage module 5000 is grounded through the direct connection with the bottom frame 11. Furthermore, the direct connection between the bottom frame 11 and the base board 30 has the grounding effect, too. As shown in FIG. 2, in addition to the current direction described above, the storage module 5000 is also grounded by the direct connection with the side frame 12 and the movable housing 20.

Moreover, the present disclosure is not limited to the amount of the fixing slots 111, hooks 112, elastic electrically connecting plates 33 and 113, fixing bulges 1211 and 1231, electrically connecting parts 1221 and 24, keyhole-shaped installing holes 1222 and 25, blocks 21, fixing notches 22 and 23, locating walls 31, interlock grooves 32 and buffer pins 40 in the above figures and descriptions. According to different situations and requirements, the amounts of the components are adjustable in other embodiments.

According to the fixation structure for the storage module disclosed in the embodiments of the present disclosure, the fixed housing and the movable housing are made by metal so as to directly and electrically connect to the storage module for grounding and avoiding electromagnetic interference. Therefore, there is no need for setting additional conductive pad and conductive fabric which increases the production cost. Furthermore, the storage module is installed on the fixed housing first, and then the movable housing is interlocked with the fixed housing to finish the fixation of the storage module. Thereby, the present disclosure of the fixation structure for the storage module increases the assembling efficiency and the detaching efficiency.

What is claimed is:

1. A fixation structure, for accommodation and fixing a storage module, comprising:
an accommodating housing, comprising:
a fixed housing, including a bottom frame and a side frame, the side frame standing on three adjacent sides of the bottom frame to form an opening therebetween; and
a movable housing detachably installed on the bottom frame for closing the opening so as to form an accommodating room with the fixed housing, and the storage module being installed inside the accommodating room;
wherein the fixed housing and the movable housing are made of metal.

2. The fixation structure of claim 1, wherein the bottom frame has a fixing slot, and the movable housing has a block which is detachably installed in the fixing slot of the bottom frame.

3. The fixation structure of claim 1, wherein the side frame comprises a first side frame, a second side frame and a third side frame which are fixed on the three adjacent sides of the bottom frame, respectively, and two opposite ends of the second side frame are connected to one end of the first side frame and one end of the third side frame, respectively, and the opening is formed between the first side frame and the third side frame.

4. The fixation structure of claim 3, wherein each of the first side frame and the third side frame has a fixing bulge, and each of two opposite ends of the movable housing has a fixing notch; the fixing bulges and the fixing notches are detachably interlocked with each other.

5. The fixation structure of claim 3, wherein the first side frame has a through hole for exposing a connecting slot of the storage module.

6. The fixation structure of claim 1, wherein each of the side frame and the movable housing has an electrically connecting part extending toward the accommodation room, and the electrically connecting parts are electrically connect to the storage module.

7. The fixation structure of claim 1, further comprising a base board, four buffer pins and four locating walls, the bottom frame being detachably installed on the base board, the four locating walls set on the base board, each of the side frame and the movable housing having a keyhole-shaped installing hole in which the buffer pins are installed, one end of the buffer pins pressed against the storage module, and the other end of the buffer pins pressed against the locating walls, respectively, when the accommodate housing is installed on the base board so as to fix the storage module on the base board.

8. The fixation structure of claim 7, wherein the base board has an interlock groove, and the bottom frame of the fixed housing comprises a hook which is detachably interlocked to the interlock groove of the base board.

9. The fixation structure of claim 7, wherein the base board comprises an elastic electrically connecting plate extending toward the bottom frame for directly connecting to the bottom frame.

10. The fixation structure of claim 1, wherein the bottom frame comprises an elastic electrically connecting plate extending toward the accommodating room for directly connecting to the storage module.
